(19) United States
(12) Patent Application Publication
(10) Pub. No.: US 2025/0239556 A1
(43) Pub. Date: Jul. 24, 2025

(54) PACKAGE DEVICE

(71) Applicant: InnoLux Corporation, Miao-Li County (TW)

(72) Inventors: Ker-Yih KAO, Miao-Li County (TW); Cheng-Che WU, Miao-Li County (TW); Wei-Yuan CHENG, Miao-Li County (TW); Lung-Shu HUANG, Miao-Li County (TW)

(73) Assignee: InnoLux Corporation, Miao-Li County (TW)

(21) Appl. No.: 18/986,725

(22) Filed: Dec. 19, 2024

Related U.S. Application Data
(60) Provisional application No. 63/622,084, filed on Jan. 18, 2024.

(30) Foreign Application Priority Data
Sep. 6, 2024 (CN) 202411244912.3

(51) Int. Cl. H01L 23/00; H01L 23/31; H01L 25/07

(52) U.S. Cl. CPC H01L 24/24; H01L 23/3135; H01L 24/25; H01L 25/072; H01L 2224/24137; H01L 2224/244; H01L 2224/2518

(57) ABSTRACT

A package device includes a first electronic component, a second electronic component, a conductive component, a package layer, and a circuit structure. The package layer surrounds the first electronic component, the second electronic component, and the conductive component. The circuit structure is disposed on the package layer, and a first bonding pad of the first electronic component is electrically connected to a second bonding pad of the second electronic device through the circuit structure and the conductive component. A first distance is between a surface of the first electronic component and a first surface of the package layer, and a second distance is between a surface of the second electronic component and a second surface of the package layer.

### CROSS REFERENCE TO RELATED APPLICATION

This application claims the benefit of U.S. Provisional Application No. 63/622,084, filed on Jan. 18, 2024. The content of the application is incorporated herein by reference.

### BACKGROUND OF THE DISCLOSURE

### 1. Field of the Disclosure

The present disclosure relates to a package device and particularly to a package device with a conductive via structure piercing through a package layer.

### 2. Description of the Prior Art

With the advancement of semiconductor packaging technology, it has been developed to package multiple chips in one package. In a conventional package structure, the chips need to be encapsulated by a package material to protect the chips. However, as the thickness of the package material increases, a through hole is not easily formed in the package material. For example, the through hole with poor quality is formed, which causes inferior quality of a conductive layer formed in the through hole afterwards or void in the conductive layer, lowering the product yield.

### SUMMARY OF THE DISCLOSURE

It is an objective of the present disclosure to provide a package device to form a conductive component and to enhance the yield.

According to an embodiment of the present disclosure, a package device is disclosed, and the package device includes a first electronic component, a second electronic component, a conductive component, a first package layer, and a first circuit structure. The first electronic component and the second electronic component are disposed side by side, and the conductive component is disposed on a side of the first electronic component. The first package layer surrounds the first electronic component, the second electronic component, and the conductive component, wherein the first package layer includes a first surface and a second surface opposite to the first surface, the first electronic component includes a first bonding pad adjacent to the first surface, and the second electronic component includes a second bonding pad adjacent to the second surface. The first circuit structure is disposed on the first package layer, wherein the first bonding pad of the first electronic component is electrically connected to the second bonding pad of the second electronic component through the first circuit structure and the conductive component. A first distance is between a surface of the first electronic component and the first surface of the first package layer, and a second distance is between a surface of the second electronic component and the second surface of the first package layer.

In the package device of the present disclosure, the bonding pad and the conductive component may form a conductive via structure piercing through the package layer. Hence, a through hole with high aspect ratio does not need to be formed in the package layer, such that the problem of void or insufficient yield rate caused by poor quality of through hole and the problem of time-consuming drilling hole multiple times may be avoided and yield of the package device may be enhanced. In addition, with the first distance and the second distance, the possibility of wire breakage of the trace on the surface of the electronic component and the first surface of the package device may be lowered.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 6 schematically illustrates a cross-sectional view of a structure in different steps of a manufacturing method of a package device according to a first embodiment of the present disclosure.

FIG. 7 schematically illustrates a cross-sectional view of a package device according to a first modified embodiment of the first embodiment of the present disclosure.

FIG. 8 schematically illustrates a cross-sectional view of a package device according to a second modified embodiment of the first embodiment of the present disclosure.

FIG. 9 schematically illustrates a cross-sectional view of a package device according to a third modified embodiment of the first embodiment of the present disclosure.

FIG. 10 schematically illustrates a cross-sectional view of a package device according to a fourth modified embodiment of the first embodiment of the present disclosure.

FIG. 11 to FIG. 13 schematically illustrates a cross-sectional view of a structure in different steps of a manufacturing method of a package device according to a second embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the components in the drawings are just illustrative and are not intended to limit the scope of the present disclosure.

Certain terms are used throughout the specification and the appended claims of the present disclosure to refer to specific components. Those skilled in the art should understand that electronic equipment manufacturers may refer to a component by different names, and this document does not intend to distinguish between components that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the components of the claims. It does not mean that the component has any previous ordinal numbers, nor does it represent the order of a certain component and another component, or the sequence in a manufacturing method. These ordinal numbers are just used to make a claimed component with a certain name be clearly distinguishable from another claimed component with the same name.

In addition, when one component or layer is “on” or “above” another component or layer or is “connected to” the another component or layer, it may be understood that the component or layer is directly on the another component or layer or directly connected to the another component or layer, and alternatively, another component or layer may be between the component or layer and the another component or layer (indirectly). On the contrary, when the component or layer is “directly on” the another component or layer or is “directly connected to” the another component or layer, it may be understood that there is no intervening component or layer between the component or layer and the another component or layer. Besides, the term “electrically connected to” or “coupled to” includes any direct or indirect means of electrical connection.

In the following contents, when one component is called “disposed on” another component, it does not limit the manufacturing method or sequence of the component or the another component.

As disclosed herein, the terms “approximately”, “essentially”, “about”, or “substantially” generally mean within 20%, 10%, 5%, 3%, 2%, 1%, or 0.5% of the reported numerical value or range. Numbers given herein is an approximated number, that is, without specifically describing with the terms “approximately”, “essentially”, “about”, or “substantially”, it may imply the meaning of the terms “approximately”, “essentially”, “about”, or “substantially”.

The term “between number A and number B” may be interpreted as situation of including number A and number B or including at least one of number A and number B, and may be interpreted as other numbers between number A and number B.

In the present disclosure, the depth, thickness, length, width, and radius may be measured by using an optical microscope (OM), a scanning electron microscope (SEM) or other approaches, but not limited thereto.

In the present disclosure, the definition of roughness judgment may be observing an uneven surface to obtain a distance of 0.15 micrometers (μm) to 1 μm between a peak and a valley of the surface using SEM. The measurement of roughness judgment may include using SEM, transmission electron microscope (TEM), etc. to observe peaks and valleys of the surface in the same proper magnified ratio, and the range of roughness is obtained by taking a sample with a unit length (e.g., 10 μm) and then comparing the peaks and the valleys. Here, the term “proper magnified ratio” means at least one surface may be observed with roughness (Rz) or averaged roughness (Ra) of at least 10 peaks in the visual field in this magnified ratio.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

A package device of the present disclosure may, for example, be applied to any kind of electronic device. An electronic device may, for example, include a display device, a light-emitting device, a sensing device, an antenna device, a touch device, a tiled device, a package device or other suitable electronic devices, but not limited thereto. The electronic device of the present disclosure may, for example, be a bendable, stretchable, foldable, rollable, or flexible electronic device, but not limited thereto. The display device may, for example, be applied to laptop, public display, tiled display, display for car, touch display, television, monitor, smartphone, tablet, light source module, illumination apparatus, military equipment, or any electronic device applicable to the aforementioned product, but not limited thereto. The sensing device may, for example, be a sensing device used for detecting variation in capacitances, light, heat, or ultrasound, but not limited thereto. The sensing device may, for example, include a biosensor, a touch sensor, a fingerprint sensor, other suitable sensors, or any combination of sensors mentioned above. The display device may include liquid crystal molecules, a light emitting diode, a fluorescent material, a phosphor material, other suitable display medium, or any combination of elements mentioned above, but not limited thereto. The light emitting diode may, for example, include an organic light emitting diode (OLED), a mini light emitting diode (mini LED), a micro light emitting diode (micro LED), a quantum dot (QD), a quantum dot light emitting diode (e.g., QLED or QDLED), other suitable materials, or any combination of the aforementioned materials, but not limited thereto. The antenna device may, for example, include liquid crystal antenna or antennas of other types, but not limited thereto. The tiled device may, for example, include a tiled display device or a tiled antenna device, but not limited thereto. Furthermore, the appearance of the transparent display device may be, for example, rectangular, circular, polygonal, a shape with curved edges, curved or other suitable shapes. The electronic device may have peripheral systems such as a driving system, a control system, a light source system, a shelf system, etc. The electronic device may include electronic units, in which the electronic units may include a passive component and an active component, and for example include a capacitor, a resistor, an inductor, a diode, a transistor, a sensor, etc. It is noted that the electronic device of the present disclosure may be any combination of the above-mentioned devices, but not limited thereto. The manufacturing method of the package device of the present disclosure may, for example, be applied to a wafer-level package (WLP) process or a panel-level package (PLP) process, wherein the WLP process or the PLP process may include chip-first process or chip-last process, but not limited thereto. The package device of the present disclosure may, for example, be applied to a power module, a display device, a light-emitting device, a backlight device, an antenna device, a sensing device, or a tiled device, but not limited thereto. The package device may include system on a chip (SoC), system in a package (SiP), antenna in package (AiP), or any combination of the aforementioned devices, but not limited thereto.

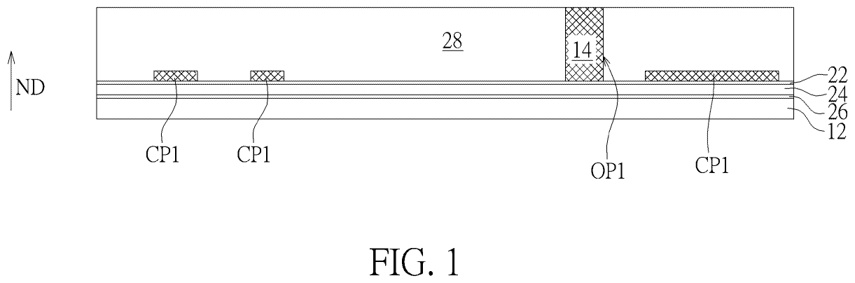

FIG. 1 to FIG. 6 schematically illustrates a cross-sectional view of a structure in different steps of a manufacturing method of a package device according to a first embodiment of the present disclosure, wherein 6 FIG. schematically illustrates a cross-sectional view of a package device according to the first embodiment of the present disclosure. A manufacturing method of a package device of the present disclosure may include following steps, and the manufacturing method of the package device is not limited to the following steps, which means other steps may be performed before, after, or during any one of steps shown. As shown in FIG. 1 to FIG. 6, the manufacturing method of the package device 1 of this embodiment may include forming at least one conductive component 14 on a carrier 12 and disposing a plurality of electronic components 16 side by side and on the carrier 12, forming a package layer 18 surrounding the electronic components 16 and the conductive component 14, removing the carrier 12 and forming a circuit structure 20 on the package layer 18. The package layer 18 may include a first surface S1 and a second surface S2 opposite to the first surface S1. One of the electronic components 16 (e.g., an electronic component 16a in the following contents) may include a bonding pad P adjacent to the first surface S1, another one of the electronic components 16 (e.g., an electronic component 16b in the following contents) may include another bonding pad P adjacent to the second surface S2, and the bonding pad P is electrically connected to the another bonding pad P through the circuit structure 20 and the conductive component 14. By forming the conductive component 14 before forming the package layer 18, it may help forming a conductive via structure penetrating through the package layer 18, such that the bonding pad P of the electronic component 16 adjacent to first surface S1 may be electrically connected to the another bonding pad P of the another electronic component 16 adjacent to the second surface S2, which may improve the quality of the package device 1.

The following contents will describe the manufacturing method of the package device 1 of this embodiment with reference to FIG. 1 to FIG. 6. As shown in FIG. 1, firstly, the carrier 12 is provided. Then, a seed layer 22 is formed on the carrier 12, and a plurality of bonding pads CP1 and at least one conductive component 14 are formed on the seed layer 22. The seed layer 22 may facilitate the formation of the bonding pads CP1 and the conductive component 14 on the carrier 12. The carrier 12 may, for example, include steel plate, transparent glass substrate, silicon substrate, or other suitable substrates. The carrier 12 may be used for carrying layers, and the thickness of the carrier 12 may be between 0.1 millimeters (mm) and 30 mm. According to some embodiments, the area of the carrier 12 may, for example, be 310 mm*310 mm, 510 mm*510 mm, or 700 mm*700 mm, but not limited thereto. The seed layer 22 may, for example, include copper, nickel, gold, titanium, tantalum, titanium nitride, other suitable materials, or any combination of the aforementioned materials. The method of forming the seed layer 22 may, for example, include a deposition process, an atomic layer deposition process, or other suitable processes.

In the embodiment of FIG. 1, before forming the seed layer 22, a release layer 24 may be formed on the carrier 12 to help to release the package layer 18, the electronic components 16, and the conductive component 14 formed afterwards from the carrier 12. The releasing method of the release layer 24 may include light releasing, thermal releasing, other suitable methods, or a combination of the aforementioned two methods. For example, with different releasing methods, the release layer 24 may adapt with different types of the carrier 12, such as the release layer 24 of light releasing type may adapt with transparent glass substrate, and the release layer 24 of thermal releasing type may adapt with steel plate. The release layer 24 may, for example, include ultraviolet (UV) release tape, heat release tape (HRT), other suitable materials, or any combination of the aforementioned two materials.

In some embodiments, before forming the release layer 24, an anti-warpage layer 26 may optionally be formed on the carrier 12 to reduce warpage produced during the following processes, such that the process yield may be enhanced. Disposition of the anti-warpage layer 26 may be determined according to the need of stress variation acting on layers on the anti-warpage layer 26 or density of conductive layers (e.g., a density of conductive layers of a circuit structure 30 in the following contents) on the anti-warpage layer 26, but not limited thereto. The anti-warpage layer 26 may, for example, include silicon oxide, silicon nitride, silicon oxynitride, tetrathoxysilane (TEOS), or other suitable materials. Furthermore, in a normal direction ND of the carrier 12, tendencies of warpage of the anti-warpage layer 26 and the circuit structure 30 formed afterwards are opposite to each other. Hence, the warpage produced in the following processes may be reduced. For example, two edges of the anti-warpage layer 26 bend downward and two edges of the circuit structure 30 bend upward, so that stress of bending upward and stress of bending downward may consequently cancel each other to maintain the evenness of the whole structure.

In the embodiment of FIG. 1, the bonding pads CP1 may be formed before forming the conductive component 14, but not limited thereto. The method of forming the bonding pads CP1 may, for example, include forming a conductive layer on the seed layer 22 and patterning the conductive layer to form the bonding pads CP1, or may alternatively include using a mask pattern exposing the seed layer 22 and then forming the bonding pads CP1 on the exposed seed layer 22. The bonding pads CP1 may be used for being bonded with the electronic components 16 disposed afterwards. After the bonding pads CP1 are formed, a mask pattern 28 may be formed on the bonding pads CP1 and the seed layer 22, wherein the mask pattern 28 includes an opening OP1 exposing the seed layer 22. Then, the conductive component 14 is formed on the seed layer 22 exposed by the opening OP1. The method of forming the conductive layer, the bonding pads CP1, and the conductive component 14 may, for example, include evaporation, sputtering, electroplating, electroless plating, deposition, or other suitable processes. The conductive layer and the conductive component 14 may, for example, include copper (Cu), titanium (Ti), aluminum (Al), molybdenum (Mo), nickel (Ni), ruthenium (Ru), tantalum (Ta), tungsten (W), nitride, carbide, other suitable conductive materials, or any combination of the aforementioned materials, but not limited thereto. The mask pattern 28 may, for example, include photoresist materials or other suitable mask materials. The photoresist material may, for example, include dry film photoresist or other suitable types of photoresist. The method of forming the mask pattern 28 may, for example, include exposure and development processes or other suitable processes. According to some embodiments, the seed layer 22 may be neglected, and a conductive film may be directly formed on the release layer 24, such as attaching copper foil or lead frame to the release layer 24.

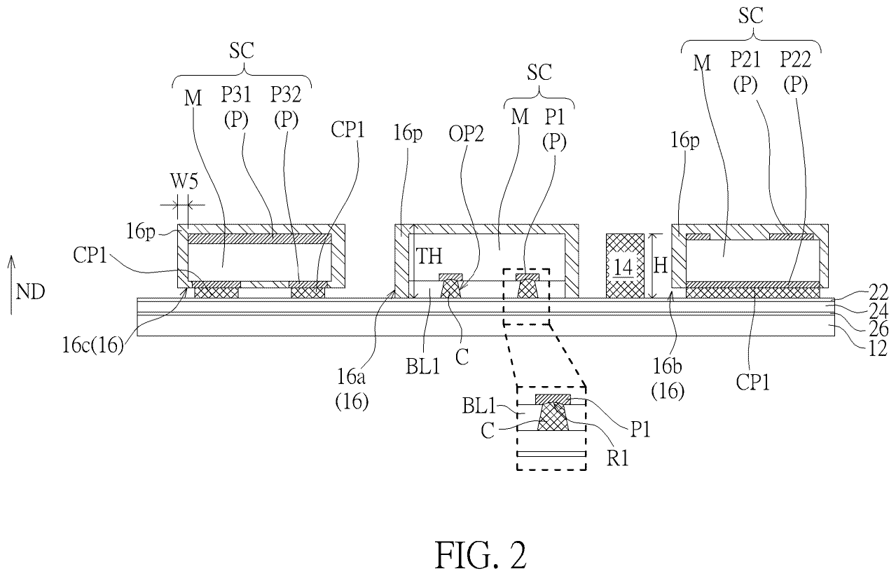

As shown in FIG. 2, after the conductive component 14 is formed, the mask pattern 28 may be removed. Afterwards, the plurality of electronic components 16 are disposed on the bonding pads CP1 and the seed layer 22. Steps of disposing the electronic components 16 may, for example, include a die bonding process, a pick-and-place process, a flipped chip process, or other suitable processes. Each of the electronic components 16 may at least include a semiconductor chip SC, wherein the semiconductor chip SC may include a body M and a plurality of bonding pads P, and the bonding pads P are disposed on the body M. The body M may, for example, include an integrated circuit. The bonding pads P may, for example, be signal input/output pads of the semiconductor chip SC. In the embodiment of FIG. 2, at least one of the electronic components 16 may include a package layer 16p surrounding the semiconductor chip SC to protect the semiconductor chip SC. In other words, the semiconductor chip SC of the electronic component 16 may be protected by the package layer 16p before being disposed on the seed layer 22 to reduce the possibility of damaging. In some embodiments, the electronic component 16 may alternatively not include the package layer 16p. The semiconductor chip SC described in the present disclosure includes a substance or a material with conductivity between insulator and conductor. The material of the semiconductor chip SC may include silicon, germanium, gallium arsenide, indium phosphide, gallium nitride, zinc oxide, aluminum nitride, silicon carbide, etc.

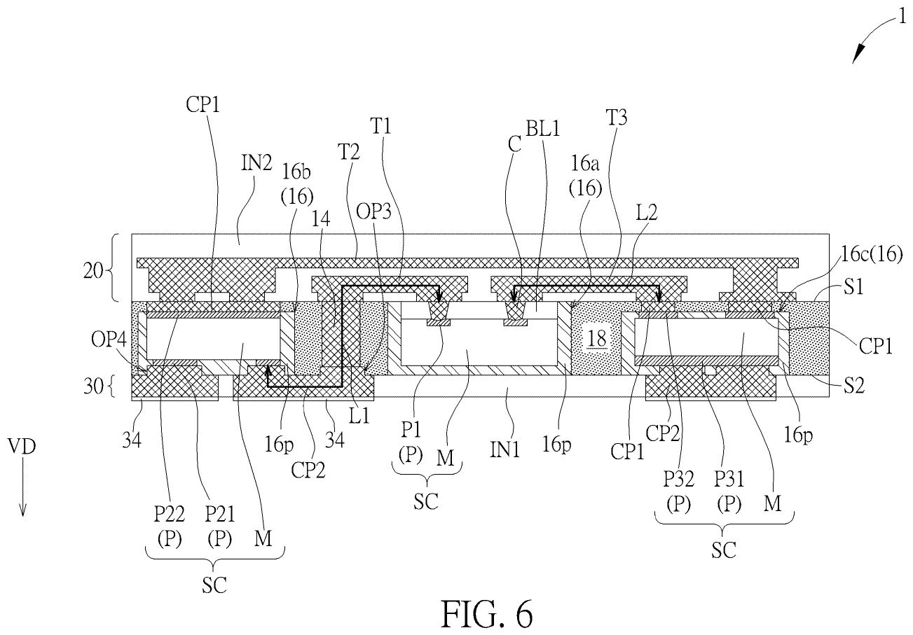

In the embodiment of FIG. 2, the electronic components 16 may include the electronic component 16a and the electronic component 16b disposed side by side, but not limited thereto. In an embodiment, the bonding pads P of the electronic component 16a may include a plurality of bonding pads P1 disposed on a surface of the body M adjacent to the carrier 12, but not limited thereto. The electronic component 16a, besides including the semiconductor chip SC and the package layer 16p, may further include a buffer layer BL1 and a plurality of conductive members C, wherein the buffer layer BL1 may be disposed on the semiconductor chip SC, and the buffer layer BL1 may include a plurality of openings OP2 respectively corresponding to the bonding pads P1. The conductive members C may be disposed in the openings OP2 and may be electrically connected to the corresponding bonding pad P1, respectively. Under this circumstance, the formed package layer 16p may further surround the buffer layer BL1. When the electronic component 16a is disposed on the carrier 12, the conductive members C of the electronic component 16a may be in direct contact with the seed layer 22, but not limited thereto. In some embodiments, a thickness TH of the electronic component 16 may be greater than or equal to a height H of the conductive component 14 to reduce the conductive component 14 from being damaged during the following processes, but not limited thereto. A thickness of a component described in the present disclosure may, for example, be measured in the normal direction ND of the carrier 12. According to some embodiments, a material of the package layer 16p may include organic or inorganic insulation materials. The organic insulation material may include epoxy, polymer, or other suitable materials. The inorganic material may include silicon oxide, silicon nitride, silicon oxynitride, aluminum oxide, titanium dioxide, or other suitable materials. Furthermore, in a direction perpendicular to the normal direction ND of the carrier 12, a width W5 of the package layer 16p on a sidewall of the semiconductor chip SC is greater than or equal to 0.1 μm and less than or equal to 5 μm. According to some embodiments, the coefficient of thermal expansion of the package layer 16p may be greater than or equal to 0.1 ppm/° C. and less than or equal to 10 ppm/° C., or the coefficient of thermal expansion of the package layer 16p may be greater than or equal to 0.5 ppm/° C. and less than or equal to 8 ppm/° C. According to some embodiments, the intrinsic stress of the package layer 16p may be greater than-1000 million pascals (MPa) and less than or equal to +800 MPa. The package layer 16p with the aforementioned intrinsic stress may compensate mechanical characteristic of the electronic component 16a to balance stress acting thereon, such that the reliability of the electronic device (e.g., the electronic device 1 shown in FIG. 6) may be enhanced. Furthermore, according to some embodiments, the thickness and the refractive index of the package layer 16p may be measured using spectroscopic reflectometry, and the intrinsic stress of the package layer 16p may be determined by the difference between the refractive indices.

For example, before the semiconductor chip SC is disposed on the carrier 12, the buffer layer BL1 may be attached to the semiconductor chip SC in order to reduce crack or fracture of the semiconductor chip SC. In addition, the conductive members C may be formed in the openings OP2 of the buffer layer BL1 to be used as the bonding pads of the electronic component 16a. The conductive members C may, for example, include similar or identical materials to that of the conductive component 14, and hence, it may be referred to the above-mentioned contents. In some embodiments, the conductive member C may further include a seed layer, but not limited thereto. In some embodiments, before forming the conductive members C, a cleaning process is performed on the bonding pads P1, and thus, a surface of each of the bonding pads P1 facing the corresponding conductive member C may have a recess R1. Besides, the conductive members C may be respectively formed in the recesses R1, and consequently, the resistance between the conductive member C and the corresponding bonding pad P1 may be reduced to enhance efficiency of conductivity. A depth of the recess R1 may, for example, be between 0.03 μm and 5 μm, or may be between 0.05 μm and 3 μm. In this embodiment, the cleaning process may include wet etching, dry etching, plasma treatment, laser treatment, or other suitable processes.

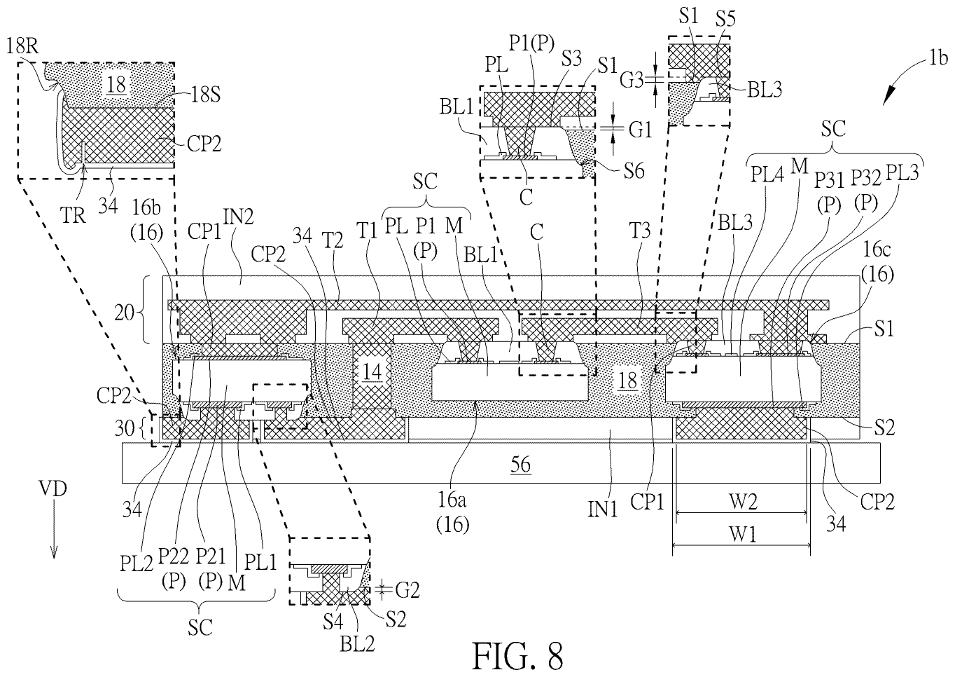

Besides, the bonding pads P of the electronic component 16b may include at least one bonding pad P21 and at least one bonding pad P22 respectively disposed on a surface of the body M away from the carrier 12 and the surface of the body M adjacent to the carrier 12. In the embodiment of FIG. 2, the package layer 16p may not cover the bonding pad P22 so as to expose the bonding pad P22, and the package layer 16p may cover the bonding pad P21 to protect the bonding pad P21. When the electronic component 16b is disposed on the carrier 12, the bonding pad P22 may be bonded to one of the bonding pads CP1. The number of the bonding pad P22 may, for example, be plural, but not limited thereto. In some embodiments, the electronic component 16b may optionally further include a buffer layer, such as a buffer layer BL2 shown in FIG. 8.

In some embodiments, the electronic components 16 may further include an electronic component 16c disposed side by side with the electronic component 16a, wherein the bonding pads P of the electronic component 16c may optionally include at least one bonding pad P31 and at least one bonding pad P32 respectively disposed on the surface of the body M away from the carrier 12 and the surface of the body M adjacent to the carrier 12, but not limited thereto. In FIG. 2, the number of the bonding pad P32 may, for example, be plural, and when the electronic component 16c is disposed on the carrier 12, the bonding pads P32 may respectively be bonded to the plurality of bonding pads CP1, but not limited thereto. In some embodiments, the coefficient of thermal expansion of the package layer 16p may be less than the coefficient of thermal expansion of the buffer layer (e.g., the buffer layer BL1, the buffer layer BL2, and/or a buffer layer BL3), such that the buffer layer may have better buffering to protect traces of the electronic components 16 from damaging during processes, but not limited thereto.

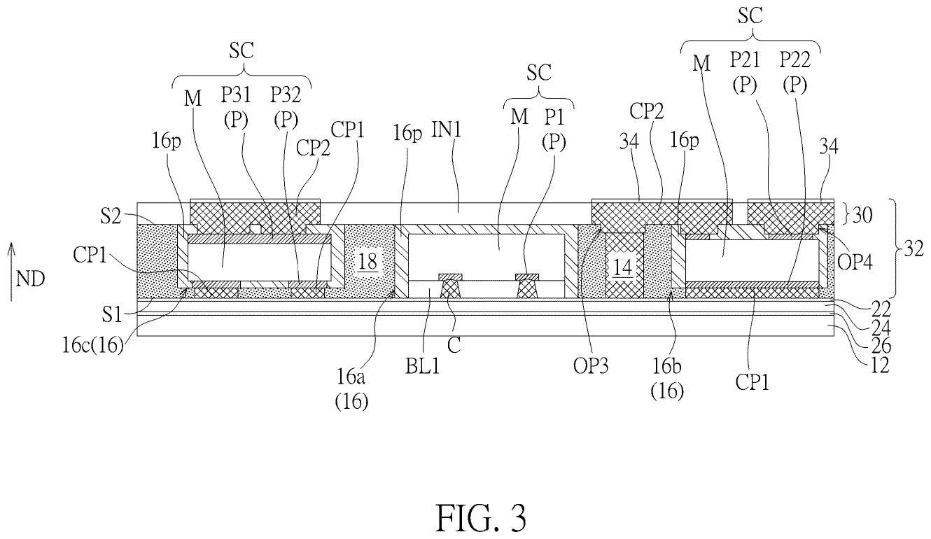

As shown in FIG. 3, after the step of disposing the electronic components 16, the package layer 18 may be formed on the electronic components 16, the conductive component 14, and the seed layer 22. Specifically, the method of forming the package layer 18 may, for example, include forming a package material on the electronic components 16, the conductive component 14, and the seed layer 22 and covering them with the package material by a molding process or other suitable methods, and then removing a portion of the package material by a grinding process, a sandblasting process, a plasma surface treatment process, a chemical mechanical polishing (CMP) process, an etching process, or other suitable processes so as to expose the package layers 16p of the electronic components 16. The package layer 18 may, for example, include molding compound or other suitable package materials. The molding compound may, for example, include epoxy or other suitable materials. According to some embodiments, the coefficient of thermal expansion of the package layer 16p may be less than or equal to that of the package layer 18 to reduce risk of crack from the interface between the package layer 16p and the package layer 18. Or, according to some embodiments, before forming the package layer 18, a surface roughening treatment may be performed on the electronic components 16 or the package layer 16p to enhance adhesion of the electronic components 16 or the package layer 16p to layers formed later, but not limited thereto.

In the embodiment of FIG. 3, the step of forming the package layer 18 may not expose the conductive component 14. That is, the step of removing the portion of the package material may not completely remove the package material on the conductive component 14. In this case, after forming the package layer 18, a patterning process may be performed to form an opening OP3 in the package layer 18 on the conductive component 14, and to form openings OP4 in the package layer 16p of the electronic component 16b and the electronic component 16c, such that the conductive component 14, the bonding pads P21 of the electronic component 16b, and the bonding pad P31 of the electronic component 16c may be exposed. Afterwards, a circuit structure 30 is formed on the package layer 18 so as to form a semi-finished product structure 32. The patterning process may, for example, include a laser process, a plasma process, a photolithography and etching process, or other suitable processes. In this embodiment, a portion of the package layer 16p of the electronic component 16b and/or a portion of the package layer 16p of the electronic component 16c may be disposed between the circuit structure 30 and the corresponding semiconductor chip SC. According to some embodiments, one of the electronic components 16 is a high side switch component, another one of the electronic components 16 is a low side switch component, and still another one of the electronic components 16 is a power management chip, but bot limited thereto.

The circuit structure 30 may be a redistribution structure including at least one conductive layer and at least one insulation layer. In the embodiment of FIG. 3, the circuit structure 30 may include one conductive layer and one insulation layer IN1, but not limited thereto. The conductive layer of the circuit structure 30 may include a plurality of bonding pads CP2 exposed by a surface of the circuit structure 30 away from the package layer 18.

In some embodiments, after forming the circuit structure 30, a conductive block 34 may be selectively formed on a surface of each of the bonding pads CP2 away from the package layer 18 to protect the bonding pads CP2 from being affected by oxygen or moisture before the bonding pads CP2 are bonded to other components. The method of forming the conductive block 34 may, for example, include electroplating, electroless plating, or other suitable methods. The conductive block 34 may include gold, tin, silver, copper, nickel, other suitable metal materials, or any combination of the aforementioned metal materials.

In some embodiments, the step of forming the package layer 18 may expose at least one of the bonding pads P21 of the electronic component 16b, the bonding pad P31 of the electronic component 16c, and the conductive component 14. When the bonding pads P21 of the electronic component 16b, the bonding pad P31 of the electronic component 16c, and the conductive component 14 are all exposed, the patterning process may not need to be performed, and the circuit structure 30 may be directly formed on the exposed bonding pads P21 of the electronic component 16b, the exposed bonding pad P31 of the electronic component 16c, and the exposed conductive component 14. In some embodiments, when the electronic components 16 may not include the package layer 16p, the step of removing the portion of the package material may be stopped as the bonding pads P21 of the electronic component 16b, the bonding pad P31 of the electronic component 16c, and the conductive component 14 are exposed.

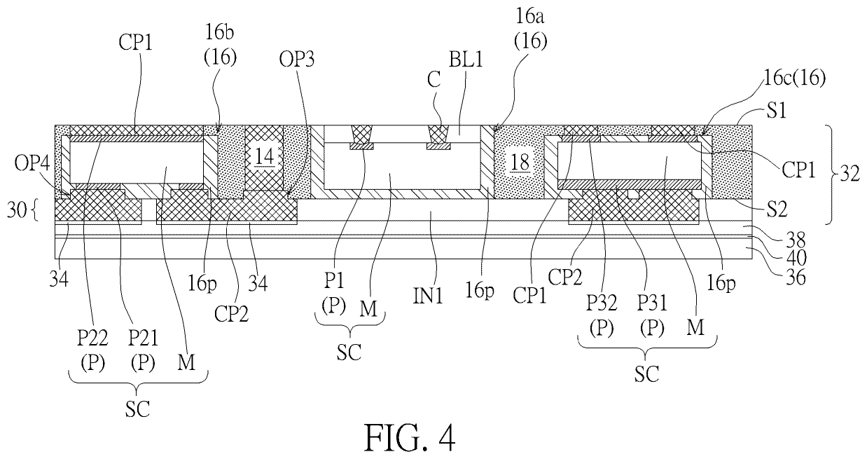

As shown in FIG. 4, after the circuit structure 30 is formed, the semi-finished product structure 32 may be flipped upside down to be transferred to another carrier 36 to expose the seed layer 22. For example, before flipping the semi-finished product structure 32, the carrier 36 may be attached to the circuit structure 30, and then the carrier 36, the semi-finished product structure 32, and the carrier 12 may be flipped upside down. Afterwards, by releasing the release layer 24, the carrier 12, the release layer 24, and the anti-warpage layer 26 may be removed. After removing the carrier 12 and the release layer 24, the exposed seed layer 22 may be further removed to expose the bonding pads CP1, the conductive component 14, the conductive members C of the electronic component 16a, and the first surface S1 of the package layer 18.

In some embodiments, between the step of removing the mask pattern 28 and the step of disposing the electronic components 16, an etching process may be optionally performed to remove an exposed portion of the seed layer 22, and portions of the seed layer 22 overlapped with the bonding pads CP1 and the conductive component 14 may remain. In this case, after removing the carrier 12 and the release layer 24, the exposed seed layer 22 may optionally not be removed, but not limited thereto.

In the embodiment of FIG. 4, before attaching the carrier 36 to the circuit structure 30, a release layer 38 may be formed on the carrier 36 to facilitate separation of the carrier 36 from the package device 1 formed afterwards. The method of releasing the release layer 38 may include light releasing, thermal releasing, other suitable methods, or a combination of any two aforementioned methods. The release layer 38 may, for example, include ultraviolet (UV) release tape, heat release tape (HRT), other suitable materials, or a combination of any two aforementioned materials. The method of releasing the release layer 38 may be identical to or different from that of the release layer 24. In some embodiments, before forming the releasing layer 38, an anti-warpage layer 40 may be optionally formed on the carrier 36 to reduce warpage produced during the following processes, such that the process yield may be enhanced. The material of the anti-warpage layer 40 may be similar or identical to that of the anti-warpage layer 26, so it may refer to the aforementioned contents, and they are not detailed redundantly herein. Disposition of the anti-warpage layer 40 may be determined according to need of stress variation acting on layers on the anti-warpage layer 40 or density of conductive layers (e.g., the density of conductive layers of the circuit structure 30 and a density of conductive layers of the circuit structure 20 formed later) formed on the anti-warpage layer 40 in the following steps, but not limited thereto.

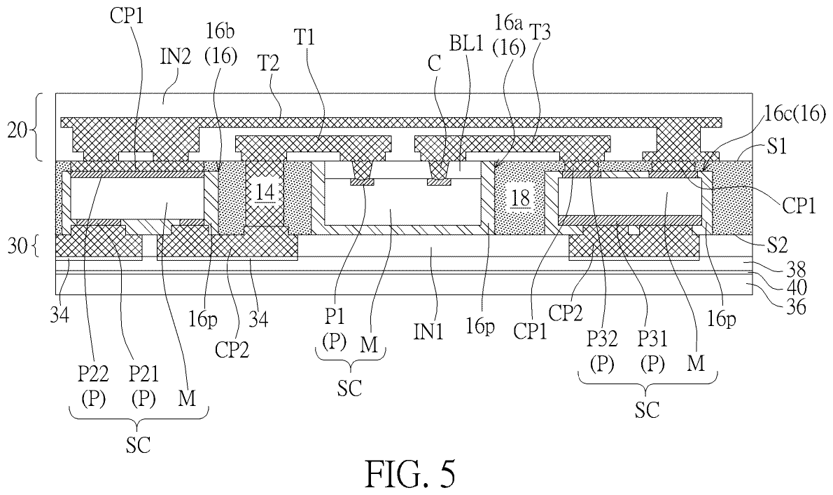

As shown in FIG. 5, afterwards, a circuit structure 20 may be formed on the first surface S1 of the package layer 18. The circuit structure 20 may be a redistribution structure including at least one conductive layer and at least one insulation layer. In FIG. 5, the insulation layer of the circuit structure 20 is illustrated with a single insulation layer IN2, and the insulation layer IN2 may include single layer or multiple insulation layers. The circuit structure 20 may include a plurality of traces, and each of the traces may be formed of at least one conductive layer according to requirements, but not limited thereto.

The materials of the conductive layers of the circuit structure 30 and the circuit structure 20 may be referred to the material of the conductive layer used for forming the bonding pads CP1, so they are not detailed redundantly herein. Each of the insulation layer IN1 and the insulation layer IN2 may include molding compound, Ajinomoto build-up film (ABF), photosensitive polyimide (PSPI), or other suitable insulation materials. In some embodiments, the coefficient of thermal expansion of the insulation layer IN1 (or the insulation layer IN2) and the coefficient of thermal expansion of the package layer 18 may be adjusted to reduce the warpage of the whole structure or to mitigate differences between the acting stresses. For example, during manufacturing processes, the warpage may be less than or equal to 3 mm, or may be less than or equal to 2 mm. In some embodiments, the insulation layer IN1 (or the insulation layer IN2) may, for example, include the same material as the package layer 18. The insulation layer IN1 and the insulation layer IN2 may, for example, include identical material or different materials.

As shown in FIG. 6, after the circuit structure 20 is formed, the carrier 36 may be removed to form the package device 1 of this embodiment. It is noted that by the aforementioned manufacturing method, the conductive component 14 may be formed before forming the package layer 18, and in combination with the step of forming the circuit structure 30, the bonding pads CP2 of the circuit structure 30 and the conductive component 14 may form the conductive via structure penetrating through the package layer 18. Hence, the probability of forming a through hole with high aspect ratio in the package layer 18 may be reduced, such that the problem of void or insufficient product yield caused by poor quality of the through hole and the problem of time-consuming caused by drilling hole multiple times may be avoided, and yield of the package device 1 may be improved. A height of the conductive component 14 may, for example, be greater than 180 μm.

As shown in FIG. 6, the package device 1 may include the electronic component 16a, the electronic component 16b, at least one conductive component 14, the package layer 18, and the circuit structure 20. The electronic component 16a and the electronic component 16b may be disposed side by side, and the conductive component 14 is disposed on a side of the electronic component 16a. The package layer 18 may surround the electronic component 16a, the electronic component 16b, and the conductive component 14, wherein the package layer 18 may have the first surface S1 and the second surface S2 opposite to the first surface S1. The electronic component 16a may include the bonding pad P1 adjacent to the first surface S1, the electronic component 16b may include the bonding pad P21 adjacent to the second surface S2, and the bonding pad P1 may be electrically connected to the bonding pad P21 through the conductive component 14 and the circuit structure 20, such that the package device 1 may have an effect of electrically connection penetrating through the package layer 18.

In the embodiment of FIG. 6, the circuit structure 20 may include a first trace T1, and one of the bonding pads P1 of the electronic component 16a may be electrically connected to one of the bonding pads P21 of the electronic component 16b through the first trace T1 and the conductive component 14. The package device 1 may further include the circuit structure 30 disposed on the second surface S2 of the package layer 18, and the one of the bonding pads P21 of the electronic component 16b adjacent to the second surface S2 of the package layer 18 may be electrically connected to the conductive component 14 through the circuit structure 30 so as to further be electrically connected to the one of the bonding pads P1 of the electronic component 16a adjacent to the first surface S1 of the package layer 18. For example, one of the bonding pads CP2 may be extended to the opening OP3 of the package layer 18 and one of the openings OP4 to electrically connect the conductive component 14 to the corresponding bonding pad P21. In other words, the bonding pad CP2 may be used as a trace electrically connecting the bonding pad P21 of the electronic component 16b to the conductive component 14. Other bonding pads CP2 may be extended to the corresponding openings OP4 to be electrically connected to another bonding pad P21 or the bonding pad P31. For example, in a cross-sectional view, a total length of the path from the bonding pad P1 of the electronic component 16a through the first trace T1, the conductive component 14, and the bonding pad CP2 to the bonding pad P21 of the electronic component 16b may be a length L1.

Besides, the boding pad P22 of the electronic component 16b adjacent to the first surface S1 of the package layer 18 may be electrically connected to one of the bonding pads P32 of the electronic component 16c adjacent to the first surface S1 of the package layer 18. In the embodiment of FIG. 6, the circuit structure 20 may further include a second trace T2, and the bonding pad P22 of the electronic component 16b may be electrically connected to the bonding pad P32 of the electronic component 16c through the second trace T2. In some embodiments, the circuit structure 20 may further include a third trace T3, and the electronic component 16a may further include another bonding pad P1 adjacent to the first surface S1 of the package layer 18, wherein the another bonding pad P1 is electrically connected to another of the bonding pads P32 of the electronic component 16c through the third trace T3. For example, in a cross-sectional view, the total length of the path from the bonding pad P1 through the third trace T3 to the bonding pad P32 of the electronic component 16c may be a length L2. The bonding pad P31 of the electronic component 16c may be adjacent to the second surface S2 of the package layer 18 and may be electrically connected to the circuit structure 30. For example, the bonding pad P31 may be further electrically connected to external components through the bonding pad CP2 of the circuit structure 30. In some embodiments, another bonding pad P21 of the electronic component 16b may be further electrically connected to external components through another bonding pad CP2 of the circuit structure 30. In this embodiment, the length L1 is greater than the length L2. In some embodiments, the length L1 may be greater than or equal to half the length L2 and less than or equal to twice the length L2 (0.5*L2≤L1≤2*L2), and with the aforementioned design, signal transmission losses may be reduced, but not limited thereto.

In the electronic component 16a, since the conductive member C may penetrate through the buffer layer BL1 and may electrically connect the semiconductor chip SC to the circuit structure 20, the bonding pad P1 may be electrically connected to the corresponding first trace T1 or the second trace T2 through one of the conductive members C. The circuit structure 20 and the circuit structure 30 of the present disclosure are not limited to the drawings and may have other layout structures.

In FIG. 6, the package device 1 may further include the conductive block 34 disposed on a surface of each of the bonding pads CP2 away from the package layer 18, and a width of the conductive block 34 may be identical to a width of an exposed surface of the corresponding bonding pad CP2, but not limited thereto. In some embodiments, as shown in FIG. 8, a width W1 of the conductive block 34 may be greater than a width W2 of the corresponding bonding pad CP2 to improve adhesion between the circuit structure 30 and other components (e.g., circuit board), such that reliability of adhesion may be enhanced. Besides, other parts of the package device 1 may be identical to the aforementioned contents, so they are not detailed redundantly herein.

The package device and manufacturing method thereof of the present disclosure are not limited to the above-mentioned embodiments and may have other embodiments or other modified embodiments. To simplify description, other embodiments or other modified embodiments in the following contents will use the same notations to the same elements from the first embodiment. To clearly clarify other embodiments or other modified embodiments, the following contents will emphasize on the differences between other embodiments and the above mentioned embodiment or between other modified embodiments and the above mentioned embodiment, and will not further elaborate for the repeated part.

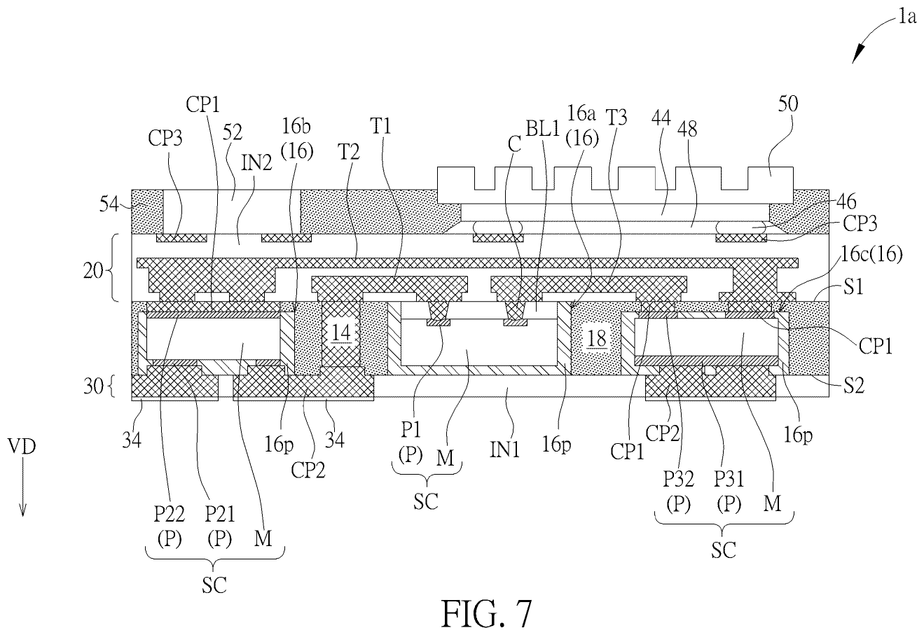

Refer to FIG. 7. FIG. 7 schematically illustrates cross-sectional view of a package device according to a first modified embodiment of the first embodiment of the present disclosure. As shown in FIG. 7, a difference between the package device 1a provided by this modified embodiment and the package device 1 shown in FIG. 6 is that the circuit structure 20 may further include a plurality of bonding pads CP3 exposed from a surface of the circuit structure 20 away from the electronic components 16 so as to be electrically connected to other components. For example, the package device 1a further includes an electronic component 44 disposed on a surface of the circuit structure 20 away from the package layer 18, and the electronic component 44 may be bonded to a part of the bonding pads CP3, such that the electronic component 44 is electrically connected to the circuit structure 20. The electronic component 44 may, for example, be bonded to the corresponding bonding pads CP3 through bonding pads 46. The bonding pad 46 may, for example, include solder ball, nickel, gold, copper, gallium, or other suitable conductive materials. In some embodiments, the electronic component 44 may optionally be electrically connected to at least one of the electronic components 16. Although FIG. 7 does not explicitly illustrate a connection structure between the bonding pads CP3 and the electronic components 16, the bonding pads CP3 of the present disclosure may, for example, be electrically connected to the corresponding electronic component 16 through traces that are not shown in FIG. 7. In some embodiments, the package device 1a may further optionally include an underfill layer 48 disposed between the electronic component 44 and the circuit structure 20 in order to enhance the adhesion between the electronic component 44 and the circuit structure 20. In some embodiments, a material of the underfill layer 48 may include an organic material or an inorganic material. The inorganic material may include silicon oxide, silicon nitride, silicon oxynitride, and the organic material may include epoxy or polymer. Alternatively, according to some embodiments, the organic material may include double or triple bond functional group to enhance reaction or increase the adhesion with other layers, but not limited thereto. In some embodiments, the material of the underfill layer 48 may further include filling particles scattered in the organic material. The filling particles may, for example, silicon dioxide, titanium dioxide, aluminum oxide, or other suitable materials, and an averaged particle size of the filling particles may be between 0.01 μm and 5 μm. In some embodiments, the coefficient of thermal expansion of the underfill layer 48 may be different from the coefficient of thermal expansion of the package layer 16p. For example, the coefficient of thermal expansion of the underfill layer 48 may be greater than the coefficient of thermal expansion of the package layer 16p, or the coefficient of thermal expansion of the underfill layer 48 may be less than the coefficient of thermal expansion of the package layer 16p. When the coefficient of thermal expansion of the underfill layer 48 is different from the coefficient of thermal expansion of the package layer 16p, the thickness of the underfill layer 48 may be different from the thickness of the package layer 16b. In some embodiments, the underfill layer 48 may be multiple layers stacked, and the materials of the multiple layers may be identical or different.

In some embodiments, the package device 1a may further optionally include a heat dissipation component 50 disposed on a surface of the electronic component 44 away from the bonding pad 46. The heat dissipation component 50 may, for example, include metal or other suitable materials. In some embodiments, the package device 1a may further include another electronic component 52 disposed on the surface of the circuit structure 20 away from the electronic components 16 and bonded to another part of the bonding pads CP3. According to some embodiments, the package device 1a may further optionally include a package layer 54 surrounding the electronic component 44 and the electronic component 52. The package layer 54 may surround a portion of the heat dissipation component 50, but not limited thereto. The electronic component 52 may, for example, include an active component, a passive component, or other suitable components. The package layer 54 may, for example, include molding compound or other suitable package materials. Other parts of the package device 1a and the manufacturing method thereof may be identical to those in the embodiment of FIG. 1 to FIG. 6, so they are not detailed redundantly herein.

Refer to FIG. 8. FIG. 8 schematically illustrates a cross-sectional view of a package device according to a second modified embodiment of the first embodiment of the present disclosure. As shown in FIG. 8, a difference between the package device 1b provide by this modified embodiment and the package device 1 shown in FIG. 6 is that the package device 1b may further include a circuit component 56, and the conductive blocks 34 may be bonded to the circuit component 56. The circuit component 56 may, for example, be circuit board or other suitable components.

In the embodiment of FIG. 8, a first distance G1 is between a surface S3 of the electronic component 16a and the first surface S1 of the package layer 18, and a second distance G2 is between a surface S4 of the electronic component 16b and the second surface S2 of the package layer 18. In other words, the surface S3 of the electronic component 16a is disposed outside the package layer 18, and the surface S4 of the electronic component 16b is disposed outside the package layer 18. For example, each of the first distance G1 and the second distance G2 may be greater than 0 and less than or equal to 10 μm to reduce possibility of wire breakage of the traces formed on surface S3 of the electronic component 16a, the first surface S1 of the package layer 18, on the surface S4 of the electronic component 16b and the second surface S2 of the package layer 18. A difference between the first distance G1 and the second distance G2 may, for example, be greater than or equal to 0 and less than or equal to 5 μm. In the present disclosure, the term “distance”, which is between a surface and another surface, is referred to a distance between an extending plane of the surface and an extending plane of the another surface in a top view direction VD.

In some embodiments, a third distance G3 is between a surface S5 of the electronic component 16c and the first surface S1 of the package layer 18. The third distance G3 may, for example, be greater than or equal to 0 and less than or equal to 10 μm. In addition, a difference between the first distance G1 and the third distance G3 may, for example, be greater than or equal to 0 and less than or equal to 5 μm. In some embodiments, at least one of the first distance G1, the second distance G2, and the third distance G3 in FIG. 8 may be applied to any one of the aforementioned embodiments or any one of the following embodiments.

In the embodiment of FIG. 8, the surface S3 of the electronic component 16a may, for example, be a surface of the buffer layer BL1 of the electronic component 16a away from the semiconductor chip SC. The electronic component 16b may further include a buffer layer BL2 disposed on a surface of the semiconductor chip SC of the electronic component 16b adjacent to the second surface S2 of the package layer 18, and a surface of the buffer layer BL2 away from the corresponding semiconductor chip SC may be the surface S4 of the electronic component 16b. The electronic component 16c may further include a buffer layer BL3 disposed on a surface of the semiconductor chip SC of the electronic component 16c adjacent to the first surface S1 of the package layer 18, and a surface of the buffer layer BL3 away from the corresponding semiconductor chip SC may be the surface S5 of the electronic component 16c.

In the embodiment of FIG. 8, the semiconductor chip SC of the electronic component 16a may further include a protection layer PL disposed between the bonding pads P1 and the buffer layer BL1, and the protection layer PL may include openings corresponding to the bonding pads P1, such that the conductive members C may be electrically connected to the bonding pads P1 through the openings, respectively. A stiffness of the buffer layer BL1 may, for example, be less than a stiffness of the protection layer PL. The semiconductor chip SC of the electronic component 16b may further include a protection layer PL1 and a protection layer PL2, wherein the protection layer PL1 is disposed between the bonding pads P21 and the buffer layer BL2 and includes at least one opening corresponding to at least one of the bonding pads P21, and the protection layer PL2 may be disposed on the bonding pad P22 and includes at least one opening corresponding to the bonding pad P22. A stiffness of the buffer layer BL2 may, for example, be less than a stiffness of the protection layer PL1 and a stiffness of the protection layer PL2. The semiconductor chip SC of the electronic component 16c may further include a protection layer PL3 and a protection layer PL4, wherein the protection layer PL3 is disposed between the bonding pad P31 and the buffer layer BL3 and includes at least one opening corresponding to the bonding pad P31, and the protection layer PL4 may be disposed on the bonding pads P32 and includes at least one opening corresponding to at least one of the bonding pads P32. A stiffness of the buffer layer BL3 may, for example, be less than a stiffness of the protection layer PL3 and a stiffness of the protection layer PL4. According to some embodiments, a corner S6 of the body M of at least one of the semiconductor chip SC adjacent to the buffer layer (e.g., the buffer layer BL1) may include an arc corner, which is, for example, formed by the cutting process of the semiconductor chip SC, but not limited thereto. The cutting process may, for example, include wheel cutting or laser cutting. In some embodiments, each of the protection layer PL, the protection layer PL1, the protection layer PL2, the protection layer PL3, and the protection layer PL4 may include at least one opening exposing the body M of the corresponding semiconductor chip SC, but not limited thereto.

In the embodiment of FIG. 8, the electronic components 16 may not include the package layer 16p, but not limited thereto. In some embodiments, the electronic components 16 of the package device 1b may alternatively and optionally include the package layer 16p shown in FIG. 6.

In some embodiments, the width W1 of at least one of the conductive blocks 34 may be greater than the width W2 of the corresponding bonding pad CP2 to improve the adhesion between the circuit structure 30 and the circuit component 56, such that the bonding reliability may be enhanced. In some embodiments, a sidewall of one of the bonding pads CP2 may not be covered by the insulation layer IN1 of the circuit structure 30, such that one of the conductive blocks 34 corresponding to the bonding pad CP2 may extend to the sidewall of the bonding pad CP2 to enhance the adhesion between the circuit structure 30 and the circuit component 56, which is shown in an enlarged view of a left portion of FIG. 8 corresponding the sidewall of the circuit structure 30. According to some embodiments, an edge of a surface 18S of the package layer 18 adjacent to the sidewall thereof and facing the bonding pad CP2 may include a recess 18R, and the corresponding bonding pad CP2 and the corresponding conductive block 34 may extend into the recess 18R, such that the area of the corresponding bonding pad CP2 in contact with the corresponding conductive block 34 may be increased to enhance the adhesion between the circuit structure 30 and the circuit component 56. According to some embodiments, a surface of one of the bonding pads CP2 facing the corresponding conductive block 34 may optionally include at least one trench TR, such that the conductive block 34 may extend into the trench TR to enhance the adhesion between the conductive block 34 and the bonding pad CP2. In some embodiments, each of the conductive blocks 34 may extend to be in contact with the sidewall of the corresponding bonding pad CP2 and may be between the corresponding bonding pad CP2 and the insulation layer IN1. Under this condition, after the conductive layer including the bonding pads CP2 is formed, the portion of the insulation layer IN1 in contact with the bonding pads CP2 may be removed, and then, by electroplating process, the conductive blocks 34 may be formed on the sidewalls of the bonding pads CP2 so as to enhance the adhesion between each of the conductive block 34 and the corresponding bonding pad CP2.

In some embodiments, the relation of the width W1 of one of the conductive blocks 34 and the width W2 of the corresponding bonding pad CP2 may also be applied to any one of the aforementioned embodiments or any one of the following embodiments. Other parts of the package device 1b and the manufacturing method thereof may be identical to those in the embodiment of FIG. 1 to FIG. 6, so they are not detailed redundantly herein.

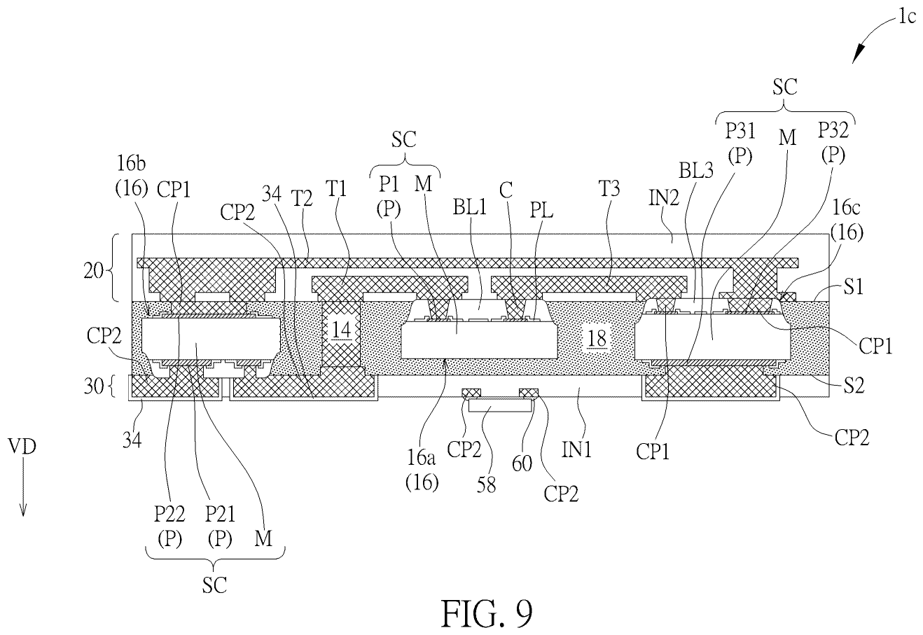

Refer to FIG. 9. FIG. 9 schematically illustrates cross-sectional view of a package device according to a third modified embodiment of the first embodiment of the present disclosure. As shown in FIG. 9, a difference between the package device 1c provided by this modified embodiment and the package device 1b shown in FIG. 8 is that the package device 1c may further include another electronic component 58 disposed on a surface of the circuit structure 30 away from the electronic components 16. The electronic component 58 may be bonded to a portion of the bonding pads CP2 of the circuit structure 30 through a bonding pad 60. The electronic component 58 may, for example, include an active component, a passive component, or other suitable components. The bonding pad 60 may, for example, be identical or similar to the aforementioned bonding pad 46, so it is not detailed redundantly herein. Other parts of the package device 1c and the manufacturing method thereof may be identical to that in the embodiment of FIG. 1 to FIG. 6, so they are not detailed redundantly herein.

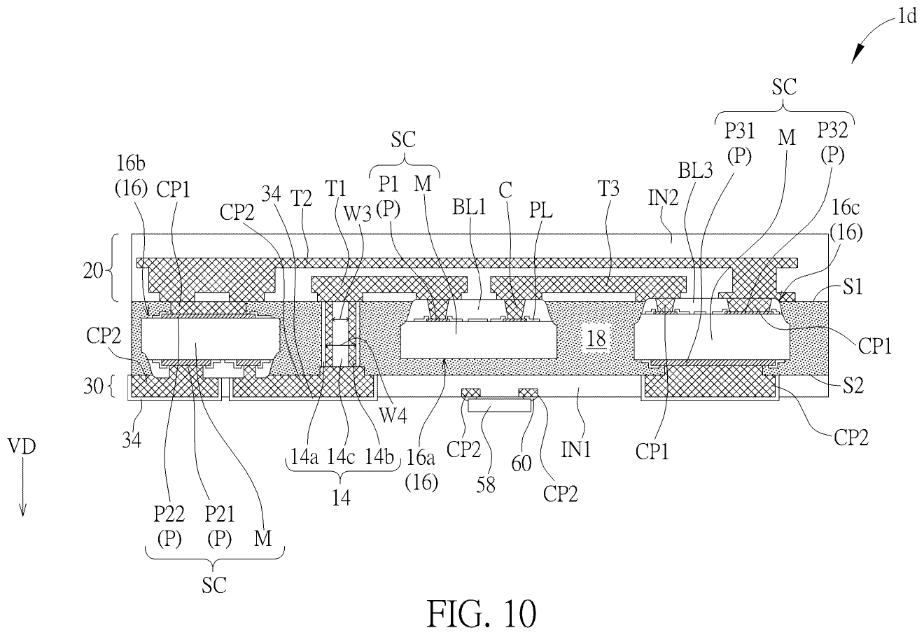

Refer to FIG. 10. FIG. 10 schematically illustrates a cross-sectional view of a package device according to a fourth modified embodiment of the first embodiment of the present disclosure. As shown in FIG. 10, a difference between the package device 1d provided by this modified embodiment and the package device 1c shown in FIG. 9 is that the conductive component 14 may include a package layer 14a, a conductive layer 14b, and a buffer layer 14c, wherein the package layer 14a may surround the conductive layer 14b, and the conductive layer 14b may surround the buffer layer 14c. In other words, the conductive component 14 may, for example, be a conductive component that is already packaged, and the conductive component 14 may, for example, be disposed on the seed layer (e.g., the seed layer 22 shown in FIG. 1) during the step of disposing the electronic components 16. Hence, the step of forming the conductive component 14 and the step of forming the mask pattern 28 may be omitted, so as to reduce production time. It is worth noting that a stiffness of the buffer layer 14c may be less than a stiffness of the package layer 14a, such that the buffer layer 14c may provide buffer as the conductive layer 14b is under thermal expansion. For example, the buffer layer 14c may include plastic, an organic material, or other suitable materials. In a cross-sectional view of the package device 1d, a ratio of a width W3 of the buffer layer 14c to a width W4 of the conductive layer 14b may, for example, be greater than or equal to 0.5 and less than 1. The width W4 of the conductive layer 14b may, for example, a distance between two interfaces between the conductive layer 14b and the package layer 14a in the cross-sectional view. In some embodiments, the conductive component 14 of FIG. 10 may also be applied to any one of the aforementioned embodiments or any one of the following embodiments. Other parts of the package device 1d and the manufacturing method thereof may be identical to those in the embodiment of FIG. 1 to FIG. 6, so they are not detailed redundantly herein.

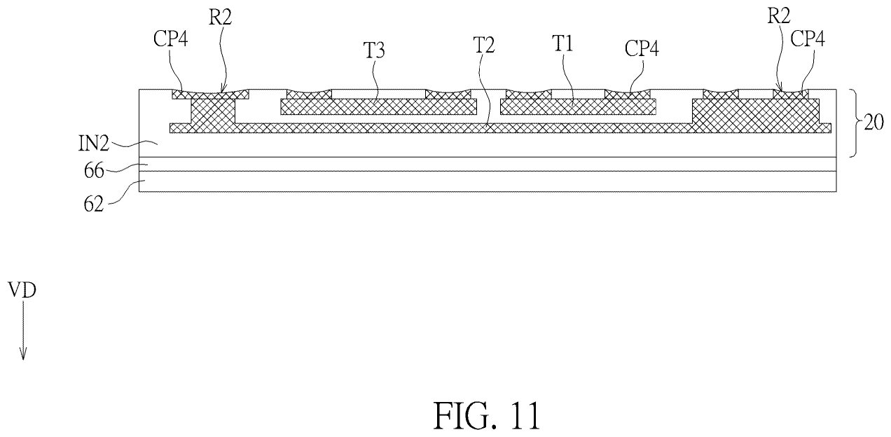

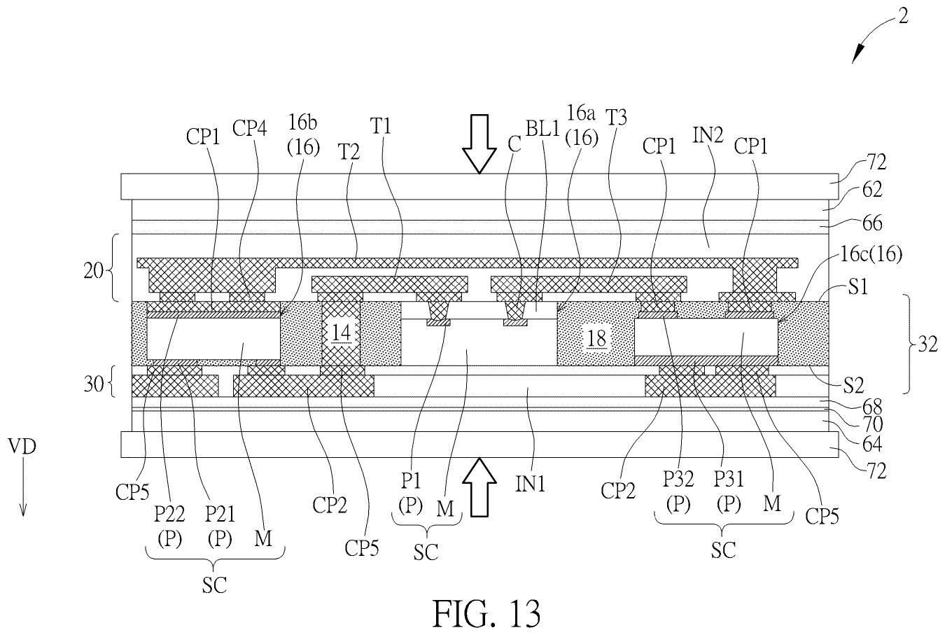

FIG. 11 to FIG. 13 schematically illustrate cross-sectional views of structures in different steps of a manufacturing method of a package device according to a second embodiment of the present disclosure, wherein FIG. 13 schematically illustrates a cross-sectional view of the package device according to the second embodiment of the present disclosure. As shown in FIG. 11 to FIG. 13, a difference between the manufacturing method of the package device 2 of this embodiment and the manufacturing method according to the aforementioned embodiments is that the circuit structure 20 and the semi-finished product structure 32 are respectively disposed on two different carriers, which are a carrier 62 and a carrier 64, and then, through a bonding process, bonding pads CP4 of the circuit structure 20 are bonded to the bonding pads of the semi-finished product structure 32, so as to form the package device 2.

Specifically, as shown in FIG. 11, the circuit structure 20 is formed on the carrier 62, wherein the circuit structure 20 may include a plurality of traces, a plurality of bonding pads CP4, and the insulation layer IN2. The bonding pads CP4 may be exposed from an upper surface of the circuit structure 20 so as to be bonded to the semi-finished product structure 32.

In some embodiments, before forming the circuit structure 20, a release layer 66 may be selectively formed on the carrier 62. In some embodiments, before forming the release layer 66, an anti-warpage layer may also be selectively formed on the carrier 62, but not limited thereto.

In some embodiments, before bonding the circuit structure 20 to the semi-finished product structure 32, a recess R2 may optionally be formed on an upper surface of each of the exposed bonding pads CP4 to reduce pressing of the circuit structure 20 and the semi-finished product structure 32 on each other during the bonding of the circuit structure 20 and the semi-finished product structure 32. A depth of the recess R2 may, for example, be less than or equal to 15 nanometers (nm). The method of forming the recess R2 may, for example, include a CMP process, an etching process, or other suitable methods.

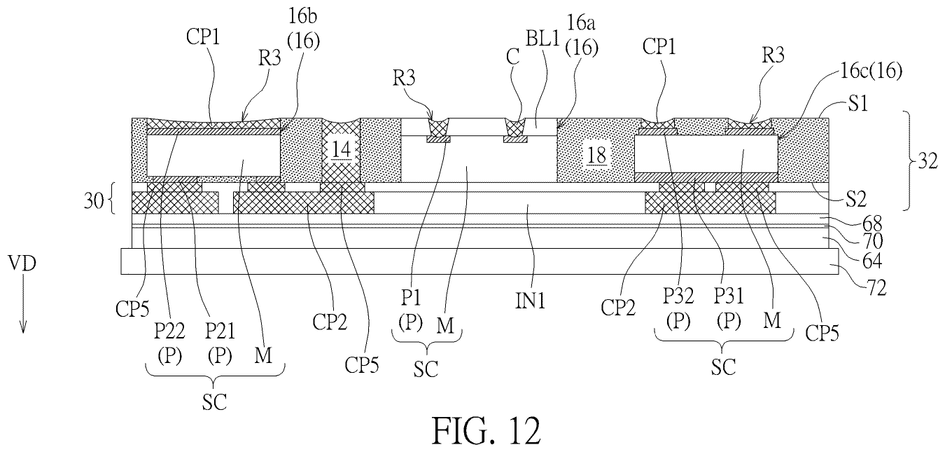

As shown in FIG. 12, the circuit structure 30 is formed on the carrier 64. Then, the conductive component 14 is formed on the circuit structure 30, and the plurality of electronic components 16 are disposed on the circuit structure 30. The circuit structure 30 may, for example, include the plurality of bonding pads CP2, a plurality of bonding pads CP5, and the insulation layer IN1, wherein the bonding pads CP2 may be electrically connected to the corresponding bonding pads CP5. The bonding pads CP2 are adjacent to the carrier 64, and lower surfaces of the bonding pads CP2 are not covered by the insulation layer IN1. An upper surface of each of the bonding pads CP5 is not covered by the insulation layer IN1, so as to be exposed from an upper surface of circuit structure 30. In some embodiments, the circuit structure 30 may further optionally include at least one trace in order to electrically connect the bonding pads CP2 to the corresponding bonding pads CP5. In some embodiments, before forming the circuit structure 30, a release layer 68 may be optionally disposed on the carrier 64. In some embodiments, before forming the release layer 68, an anti-warpage layer 70 may also be optionally formed on the carrier 64, but not limited thereto. The methods of releasing the release layer 66 and the release layer 68 and the materials of the release layer 66 and the release layer 68 may respectively use any one of the methods and materials of the aforementioned release layer 24, and may be identical to or different from the methods and materials of the aforementioned release layer 24, so they are not detailed redundantly herein. The anti-warpage layer of this embodiment may use the material of the aforementioned anti-warpage layer 26, so they are not detailed redundantly herein.

The conductive component 14 may be formed on any one of the bonding pads CP5, and the electronic components 16 may be bonded to other bonding pads CP5. The electronic components 16 may, for example, be bonded to the corresponding bonding pads CP5 through bonding pads or other suitable methods. In the embodiment of FIG. 12, the conductive component 14 may, for example, be directly formed on the corresponding bonding pad CP5 by evaporation, sputtering, electroplating, electroless plating, deposition, or other suitable processes, but not limited thereto. In some embodiments, the conductive component 14 may also use the conductive component 14 of FIG. 10. In this case, the conductive component 14 may be formed as a single independent element in advance, and then, the conductive component 14 is bonded to the corresponding bonding pad CP5.

After the conductive component 14 is formed and the electronic components 16 are disposed, the package layer 18 may be formed on the circuit structure 30, wherein the package layer 18 surrounds the electronic components 16 and the conductive component 14. Meanwhile, the electronic component 16a and the conductive component 14 may be exposed, and the package layer 18 may cover the electronic component 16b and the electronic component 16c, but not limited thereto. Afterwards, openings may be formed in portions of the package layer 18 that are on the bonding pad P22 of the electronic component 16b and the bonding pads P32 of the electronic component 16c, respectively, and the bonding pads CP1 are formed in the opening, so as to form the semi-finished product structure 32. The method of forming the package layer 18 may be identical or similar to the method of forming the package layer 18 in FIG. 3, and hence, it may refer to the above-mentioned contents, and it is not detailed redundantly herein.

After the bonding pads CP1 are formed, recesses R3 may be formed on upper surfaces of the exposed bonding pads CP1, the exposed conductive component 14, and the exposed conductive members C to reduce pressing of the circuit structure 20 and the semi-finished product structure 32 on each other during the bonding of the circuit structure 20 and the semi-finished product structure 32. A depth of the recess R3 may, for example, be less than or equal to 15 nm. The method of forming the recesses R3 may, for example, include a CMP process, an etching process, or other suitable methods.

As shown in FIG. 13, after the circuit structure 20 is formed and the semi-finished product structure 32 is formed, the circuit structure 20 may be flipped upside down to be bonded to the semi-finished product structure 32, such that the bonding pads CP4 may be bonded to the corresponding bonding pads CP1, the conductive component 14, or the corresponding conductive members C, respectively. Afterwards, by releasing the release layer 66 and the release layer 68, the carrier 62, the carrier 64, the release layer 66, the release layer 68, and the anti-warpage layer 70 may be removed, such that the package device 2 of this embodiment is formed. In some embodiments, the semi-finished product structure 32 may alternatively be flipped upside down and may be bonded to the circuit structure 20. In some embodiments, after the step of removing the carrier 62, the carrier 64, the release layer 66, the release layer 68, and the anti-warpage layer 70, the conductive blocks (e.g., the conductive blocks 34 shown in FIG. 6) may further be disposed under the bonding pads CP2 of the circuit structure 30.

In the embodiment of FIG. 13, the method of bonding the circuit structure 20 to the semi-finished product structure 32 may, for example, include disposing laminating plates 72 respectively on the carrier 62 and under the carrier 64 to perform a thermal lamination process, such that the bonding pads CP4 may be directly bonded with the corresponding bonding pads CP1, the conductive component 14, or the corresponding conductive members C to form a metal-to-metal direct bond, and then performing an annealing process. According to some embodiments, the bonding between the bonding pads CP4 and the corresponding bonding pads CP1, the conductive component 14, and the corresponding conductive members C may alternatively use bonding pads or conductive glue, or other suitable bonding methods.

In the package device 2 of this embodiment, the electronic component 16 may not include the package layer, but not limited thereto. In some embodiments, the electronic components 16 of FIG. 13 may also include the package layer 16p shown in FIG. 6.

In some embodiments, the manufacturing method of FIG. 11 to FIG. 13 may also be applied to any one of the package devices according to the aforementioned embodiments. For example, at least one of the package device 1a of FIG. 7 to the package device 1d of FIG. 10 may further include the bonding pads CP4 of FIG. 11 and the bonding pads CP5 of FIG. 12. Other parts of the package device 2 may be identical to that in the embodiment of FIG. 1 to FIG. 6, so they are not detailed redundantly herein. In some embodiments, the package device 2 may optionally use at least one of the circuit structure 20 in FIG. 7 and structures thereon, the electronic components 16, the conductive blocks 34, the circuit component 56 of FIG. 8, the electronic component 58 of FIG. 9, and the conductive component 14 of FIG. 10.

In summary, in the package device and the manufacturing method thereof of the present disclosure, since the conductive component may be formed before forming the package layer surrounding the conductive component, and the bonding pads and the conductive component may form the conductive via structure penetrating through the package layer by combining with the step of forming the circuit structure, there is no through hole with high aspect ratio need to be formed in the package layer. Accordingly, the problem of void or insufficient product yield caused by poor quality of the through hole or the problem of time-consuming caused by drilling hole multiple times may be avoided, and yield of the package device may be enhanced. In addition, with the first distance and the second distance, the possibility of wire breakage of the traces formed on the surface of the electronic components and on the first surface of the package layer may be lowered.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A package device, comprising:
a first electronic component and a second electronic component disposed side by side;
a conductive component disposed on a side of the first electronic component;
a first package layer surrounding the first electronic component, the second electronic component, and the conductive component, wherein the first package layer comprises a first surface and a second surface opposite to the first surface, the first electronic component comprises a first bonding pad adjacent to the first surface, and the second electronic component comprises a second bonding pad adjacent to the second surface; and
a first circuit structure disposed on the first package layer, wherein the first bonding pad of the first electronic component is electrically connected to the second bonding pad of the second electronic component through the first circuit structure and the conductive component,
wherein a first distance is between a surface of the first electronic component and the first surface of the first package layer, and a second distance is between a surface of the second electronic component and the second surface of the first package layer.

2. The package device according to claim 1, wherein a difference between the first distance and the second distance is greater than or equal to 0 and less than or equal to 5 micrometers.

3. The package device according to claim 1, wherein each of the first distance and the second distance is greater than 0 and less than or equal to 10 micrometers.

4. The package device according to claim 1, wherein the first circuit structure comprises a first trace, the first bonding pad of the first electronic component is electrically connected to the second bonding pad of the second electronic component through the first trace and the conductive component.

5. The package device according to claim 4, further comprising a second circuit structure disposed on the second surface of the first package layer, and the second bonding pad of the second electronic component is electrically connected to the conductive component through the second circuit structure.

6. The package device according to claim 5, wherein the second electronic component further comprises a semiconductor chip and a second package layer, the second package layer surrounds the semiconductor chip, and a portion of the second package layer is disposed between the second circuit structure and the semiconductor chip.

7. The package device according to claim 5, further comprising a conductive block, the second circuit structure comprises a third bonding pad, the conductive block is disposed on a surface of third bonding pad away from the first package layer, and a width of the conductive block is greater than a width of the third bonding pad.

8. The package device according to claim 1, further comprising a third electronic component disposed side by side with the first electronic component, wherein the third electronic component comprises a fourth bonding pad adjacent to the first surface of the first package layer, and the second electronic component comprises a fifth bonding pad adjacent to the first surface of the first package layer and electrically connected to the fourth bonding pad.

9. The package device according to claim 8, wherein the first circuit structure comprises a second trace, and the fifth bonding pad is electrically connected to the fourth bonding pad through the second trace.

10. The package device according to claim 8, wherein the first circuit structure comprises a third trace, and the first electronic component further comprises another first bonding pad adjacent to the first surface of the first package layer, wherein the another first bonding pad is electrically connected to the third electronic component through the third trace.

11. The package device according to claim 8, further comprising a second circuit structure disposed on the second surface of the first package layer, wherein the third electronic component further comprises a sixth bonding pad adjacent to the second surface of the first package layer and electrically connected to the second circuit structure.

12. The package device according to claim 1, wherein the first circuit structure comprises an insulation layer, and the insulation layer comprises a same material as the first package layer.

13. The package deice according to claim 1, wherein the conductive component comprises a third package layer, a conductive layer, and a buffer layer, the third package layer surrounds the conductive layer, and the conductive layer surrounds the buffer layer.

14. The package device according to claim 13, wherein in a cross-sectional view of the package device, a ratio of a width of the buffer layer to a width of the conductive layer is greater than or equal to 0.5 and less than 1.

15. The package device according to claim 1, wherein the surface of the first electronic component is disposed outside the first package layer, and the surface of the second electronic component is disposed outside the first package layer.

16. The package device according to claim 1, wherein the first electronic component comprises a semiconductor chip, a buffer layer, and a conductive member, wherein the buffer layer is disposed on the semiconductor chip, and the conductive member penetrates through the buffer layer and electrically connects the semiconductor chip to the first circuit structure.

17. The package device according to claim 16, wherein the first electronic component further comprises a fourth package layer surrounding the semiconductor chip and the buffer layer.

18. The package device according to claim 16, wherein the semiconductor chip comprises a body, the first bonding pad, and a protection layer, the first bonding pad is disposed on the body, and the protection layer is disposed between the first bonding pad and the buffer layer.

19. The package device according to claim 18, wherein a stiffness of the buffer layer is less than a stiffness of the protection layer.

20. The package device according to claim 1, further comprising a fourth electronic component disposed on a side of the first circuit structure away from the first package layer and electrically connected to the first circuit structure.
